(19) United States
(12) Patent Application Publication
(10) Pub. No.: US 2012/0145220 A1
(43) Pub. Date: Jun. 14, 2012

(54) DICHROIC MIRROR HAVING TRANSPARENT BONDING LAYER AND SUNLIGHT COLLECTING DEVICE HAVING SAME

(75) Inventors: CHAO-TSANG WEI, Tu-Cheng (TW); GA-LANE CHEN, Santa Clara, CA (US)

(73) Assignee: HON HAI PRECISION INDUSTRY CO., LTD., Tu-Cheng (TW)

(21) Appl. No.: 13/077,911

(22) Filed: Mar. 31, 2011

(30) Foreign Application Priority Data
Dec. 10, 2010 (TW) 99143287

(51) Int. Cl. H01L 31/052; G02B 27/14

(52) U.S. Cl. 136/246; 359/634

(57) ABSTRACT

A dichroic mirror includes a first transparent substrate. In addition, the dichroic mirror includes a first multilayer dielectric, a transparent bonding layer, a second multilayer dielectric and a second transparent substrate stacked on the first transparent substrate in that order. The second transparent substrate includes a parabolic incident surface for receiving sunlight. The dichroic mirror is configured for separating the sunlight into two light beams having different wavelength regions. The second multilayer dielectric is configured for reflecting one of the two light beams and allowing another light beam to pass through.

### BACKGROUND

1. Technical Field

The present disclosure relates to the solar energy application field, and particularly, to a dichroic mirror having a transparent bonding layer, and a sunlight collecting device including the dichroic mirror.

2. Description of Related Art

Sunlight has been widely collected for obtaining electrical energy. Most energy of the sunlight is concentrated in a wavelength range from 380 nm to 2000 nm. However, a sunlight sensor of a typical sunlight collecting device cannot sense all the sunlight in the aforementioned wavelength range. That is, the utilization of the sunlight is inefficient. Therefore, it is desired to provide a sunlight collecting device which can overcome at least one of the described shortcomings.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure.

FIG. 1 shows a cross-sectional view of a dichroic mirror in accordance with an exemplary embodiment.

FIG. 2 shows an electrical energy device including the dichroic mirror of FIG. 1 and a reflector in accordance with an exemplary embodiment.

### DETAILED DESCRIPTION

Embodiments of the present disclosure will now be described in detail and with reference to the drawings.

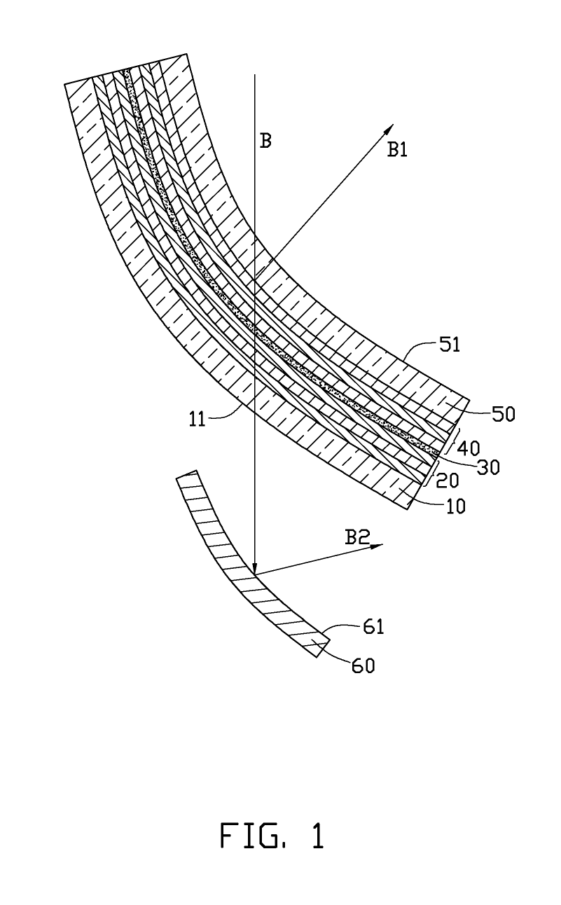

Referring to FIG. 1, a dichroic mirror 100 provided in an exemplary embodiment of the present disclosure has a parabolic cross-section, and includes a first transparent substrate 10, a first multilayer dielectric 20, a transparent bonding layer 30, a second multilayer dielectric 40 and a second transparent substrate 50 stacked on the first transparent substrate 10 in that order. The first transparent substrate 10 has a parabolic emitting surface 11, and the second transparent substrate 50 has a parabolic incident surface 51 for receiving sunlight. The first and second transparent substrates 10, 20 are made of flexible plastic films. In one embodiment, the flexible plastic film can be made of polypropylene (PP), polyethylene terephthalate (PET), or poly (arylene ether nitrile) (PEN).

The first and second multilayer dielectric 20, 40 are respectively formed on the first transparent substrate 10 and the second transparent substrate 50 using a typical chemical deposition process, physical vapor deposition process or vacuum evaporation process. The first multilayer dielectric 20 and the second multilayer dielectric 40 are directly pressed onto two opposite surfaces of the transparent bonding layer 30. Each layer of the first multilayer dielectric 20 and each layer of the second multilayer dielectric 40 can be made of a material selected from a group consisting of niobium oxide, thallium oxide, titanium oxide, silicon oxide, and aluminum oxide. The first and second multilayer dielectric 20, 40 can respectively include 15-40 layers, and a thickness of each layer is in a range from about 55 nm to 125 nm.

When sunlight, designated with capital B, irradiates onto the incident surface 51 of the second transparent substrate 50, the sunlight with wavelength in a range of about 380 nm to about 2000 nm is separated into two light beams having different wavelength ranges, herein respectively designated with capital B1, and B2. In detail, one light beam B1 passes the second transparent substrate 50, and then is reflected by the second multilayer dielectric 40, and emits out of the dichroic mirror 100 from the incident surface 51. Another light beam B2 successively passes the second multilayer dielectric 40, the bonding layer 30, the first multilayer dielectric 20, and emits out of the dichroic mirror 100 from the emitting surface 11.

In the present embodiment, the bonding layer 30 provides adhesive force, avoiding the first multilayer dielectric 20 and the second multilayer dielectric 40 respectively falling off from the first transparent substrate 10 and the second transparent substrate 50. In addition, the first and second transparent substrates 10, 50 isolates water contained in atmosphere entering into the first and second multilayer dielectric 20, 40, extending the lifetime of the dichroic mirror 100.

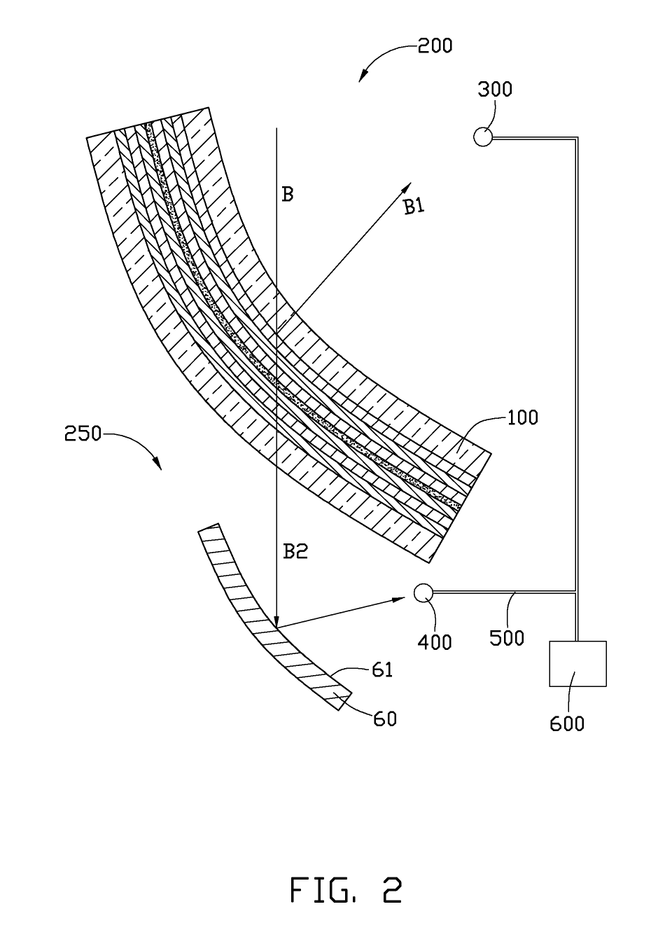

Referring also to FIG. 2, an exemplary embodiment of an electrical energy device 200 includes a sunlight collecting device 250 and a solar battery 600. The sunlight collecting device 250 transmits collected sunlight onto the solar battery 600 such that solar energy can be converted into electrical energy. In detail, the sunlight collecting device 250 includes the dichroic mirror 100, a reflector 60, a first sunlight sensor 300, a second sunlight sensor 400 and an optical fiber cable 500.

The reflector 60 has a parabolic cross-section and is arranged on a light path of the dichroic mirror 100. The reflector 60 includes a parabolic reflection surface 61 facing the first transparent substrate 10 of the dichroic mirror 100. The reflection surface 61 reflects the light beam B2.

The first sunlight sensor 300 is arranged on the focus of the dichroic mirror 100, and senses the light beam B1. The second sunlight sensor 400 is arranged on the focus of the reflector 60, and senses the light beam B2 reflected from the reflection surface 61. The first and second sunlight sensors 300, 400 optically communicate with the solar battery 600 through the optical fiber cable 500. As such, sunlight having wavelength ranged from about 380 nm to about 2000 nm is entirely transmitted to the solar battery 600, improving energy converting rate.

The described embodiments are intended to illustrate rather than limit the disclosure. Variations may be made to the embodiments and methods without departing from the spirit of the disclosure. Accordingly, it is appropriate that the appended claims be construed broadly and in a manner consistent with the scope of the disclosure.

What is claimed is:

1. A dichroic mirror, comprising:
a first transparent substrate;
a first multilayer dielectric, a transparent bonding layer, a second multilayer dielectric and a second transparent substrate positioned on the first transparent substrate in that order, the second transparent substrate comprising a parabolic incident surface for receiving sunlight; the dichroic mirror configured for separating the sunlight into two light beams having different wavelength regions, the second multilayer dielectric configured for reflecting one of the two light beams and allowing another light beam to pass through.

2. The dichroic mirror of claim 1, wherein each of the first and second transparent substrates comprises a parabolic cross-section.

3. The dichroic mirror of claim 1, wherein each of the first and second transparent substrates is comprised of a flexible plastic film.

4. The dichroic mirror of claim 1, wherein each of the first multilayer dielectric and the second multilayer dielectric is comprised of a material selected from a group consisting of niobium oxide, thallium oxide, titanium oxide, silicon oxide, and aluminum oxide.

5. The dichroic mirror of claim 1, wherein each of the first multilayer dielectric and the second multilayer dielectric comprises about 15 to 40 layers of dielectrics, a thickness of each layer of dielectric is about 55 nm to 125 nm.

6. A sunlight collecting device, comprising:
a reflector comprising a parabolic reflecting surface; and
a dichroic mirror, comprising:
a first transparent substrate;
a first multilayer dielectric positioned on the first transparent substrate;
a transparent bonding layer positioned on the first multilayer dielectric;
a second multilayer dielectric positioned on the transparent bonding layer; and
a second transparent substrate positioned on the second multilayer dielectric, the second transparent substrate comprising a parabolic incident surface for receiving sunlight, the dichroic mirror configured for separating the sunlight into two light beams having different wavelength regions, the second multilayer dielectric configured for reflecting one of the two light beams and allowing another light beam to pass through, the reflecting surface configured for reflecting the light beam passing through the second multilayer dielectric.

7. The sunlight collecting device of claim 6, wherein the reflector comprises a parabolic cross-section.

8. The sunlight collecting device of claim 6, wherein each of the first and second transparent substrates comprises a parabolic cross-section.

9. The sunlight collecting device of claim 6, wherein each of the first and second transparent substrates is comprised of a flexible plastic film.

10. The sunlight collecting device of claim 6, wherein each of the first and second multilayer dielectrics is comprised of a material selected from a group consisting of niobium oxide, thallium oxide, titanium oxide, silicon oxide, and aluminum oxide.

11. The sunlight collecting device of claim 6, wherein each of the first and second multilayer dielectrics comprises about 15 to 40 layers of dielectrics, a thickness of each layer of dielectric is about 55 nm to 125 nm.

12. The sunlight collecting device of claim 6, further comprising a first sunlight sensor and a second sunlight sensor, the first sunlight sensor arranged on a focus of the incident surface and configured for sensing the light beam reflected by the second multilayer dielectric, the second sunlight sensor arranged on a focus of the reflecting surface and configured for sensing the light beam reflected by the reflecting surface.

13. The sunlight collecting device of claim 12, further comprising an optical fiber cable optically communicating with the first sunlight sensor and the second sunlight sensor.

14. An electrical energy device, comprising:
a reflector comprising a parabolic reflecting surface;
a dichroic mirror, comprising:
a first transparent substrate;
a first multilayer dielectric positioned on the first transparent substrate;
a transparent bonding layer positioned on the first multilayer dielectric;
a second multilayer dielectric positioned on the transparent bonding layer; and
a second transparent substrate positioned on the second multilayer dielectric, the second transparent substrate comprising a parabolic incident surface for receiving sunlight, the dichroic mirror configured for separating the sunlight into two light beams having different wavelength regions, the second multilayer dielectric configured for reflecting one of the two light beams and allowing another light beam to pass through, the reflecting surface configured for reflecting the light beam passing through the second multilayer dielectric;
a first sunlight sensor arranged on a focus of the incident surface and configured for sensing the light beam reflected by the second multilayer dielectric;
a second sunlight sensor arranged on a focus of the reflecting surface and configured for sensing the light beam reflected by the reflecting surface;
a solar battery; and
an optical fiber cable optically communicating the first sunlight sensor and the second sunlight sensor to the solar battery, the optical fiber cable configured for transmitting the sunlight sensed by the first sunlight sensor and the second sunlight sensor to the solar battery.
